(19) United States
(12) Patent Application Publication
(10) Pub. No.: US 2026/0361240 A1
(43) Pub. Date: Nov. 12, 2026

(54) MULTI-STAGE MAGNETOSTRICTIVE PRELOAD FRAME FOR MEMS PIEZO-MAGNETO ENERGY HARVESTERS

(71) Applicant: Jonathan Washburn, Austin, TX (US)

(72) Inventor: Jonathan Washburn, Austin, TX (US)

(21) Appl. No.: 19/674,543

(22) Filed: May 12, 2026

Related U.S. Application Data
(60) Provisional application No. 63/804,600, filed on May 12, 2025.

(51) Int. Cl. H02N 2/18; H02N 2/00; H10N 30/30; H10N 30/88

(52) U.S. Cl. CPC H02N 2/188; H02N 2/22; H10N 30/306; H10N 30/886

(57) ABSTRACT

A micro-electromechanical vibration energy harvester includes a piezoelectric cantilever, at least one magnetostrictive preload member mechanically coupled to apply compressive preload to the cantilever, and a passive latch configured to advance and lock the preload member into two or more discrete preload states in response to vibration amplitude. The latch may be vibration-driven and self-locking such that selected preload states are retained without standby electrical power. In preferred embodiments, the harvester includes opposed magnetostrictive preload members, a pawl-and-cam latch, and a cantilever having a phi-spiral geometry for broader-band response. Increasing vibration amplitude can cause progression through successively higher locked preload states, thereby adaptively changing cantilever operating condition. Representative embodiments may include piezoelectric and magnetostrictive transduction pathways, integrated output-conditioning circuitry, and fabrication using MEMS processing techniques including structural patterning, magnetostrictive-material formation, piezoelectric-layer formation, and release of the harvester structure.

### CROSS-REFERENCE TO RELATED APPLICATIONS

This application claims the benefit of, and priority to, U.S. Provisional Patent Application No. 63/804,600, filed on May 12, 2025, the entire contents of which are incorporated herein by reference to the extent permitted.

### BACKGROUND OF THE INVENTION

The present invention relates generally to micro-electromechanical energy harvesters and, more particularly, to passive adaptive preload architectures for piezoelectric-magnetostrictive MEMS vibration harvesters in which a magnetostrictive preload structure and a vibration-driven latch cooperate to place a cantilever into discrete compressive preload states for broader-band and higher-density energy extraction from ambient vibration.

Vibration-powered MEMS harvesters have been proposed for use in self-powered sensing, telemetry, and other low-power electronic systems. In many such arrangements, a piezoelectric cantilever converts mechanical strain arising from ambient vibration into electrical output. Such arrangements, however, may be narrowband or optimized around a limited operating point, which can reduce practical performance in vibration environments having variable amplitude and frequency content. The discussion in this Background section is provided for context only and should not be treated as an admission that any particular subject matter described herein is prior art to the claimed invention except to the extent expressly stated.

Piezo-magneto MEMS harvesters can benefit from compressive preload. In particular, compressive preload can improve magnetoelastic coupling behavior and can center strain in the piezoelectric element, thereby improving electrical conversion performance. Prior approaches to preload, however, have significant limitations. Fixed preload structures, including bonded films and externally imposed preload arrangements, are generally optimized for a single operating condition and become suboptimal when the vibration environment changes. Powered tuning arrangements, including electro-thermal or other actively driven biasing structures, consume electrical power that would otherwise be available for harvesting or storage, thereby undermining the purpose of the harvester itself.

There remains a need for a MEMS harvester that can adapt to changing vibration amplitudes without requiring standby electrical power for bias adjustment. More specifically, there remains a need for a passive mechanism that can ratchet preload in discrete steps using only the vibration being harvested, can lock those preload states without continuous power consumption, and can thereby adaptively tune harvester behavior across changing vibration conditions.

### SUMMARY OF THE INVENTION

The present invention provides a MEMS vibration energy harvester comprising a piezoelectric cantilever, at least one magnetostrictive preload member mechanically coupled to apply compressive preload to the cantilever, and a passive latch configured to advance and lock the preload member into two or more discrete preload states in response to vibration amplitude. Through this arrangement, the harvester adaptively tunes operation without standby electrical power and improves energy-harvesting behavior across changing vibration conditions. The broad inventive architecture resides in the passive, vibration-driven, discrete staged-preload arrangement itself. Particular cantilever geometries, transduction pathways, verification workflows, performance relationships, and theory-linked analyses described elsewhere herein are optional or preferred implementations unless expressly stated otherwise.

In certain embodiments, the passive latch is driven by the vibration being harvested and is self-locking such that, after advancement to a selected preload state, the latch maintains that state without electrical holding power until a deliberate reset is applied. In certain embodiments, the preload states correspond to increasing vibration-amplitude thresholds and progressively increasing compressive preload imposed on the cantilever.

In preferred embodiments, the harvester includes two magnetostrictive preload members arranged around the cantilever to provide balanced compressive loading. In preferred embodiments, the latch comprises a silicon pawl-and-cam mechanism, and in further preferred embodiments the latch is inertially actuated such that increasing transverse vibration amplitude produces stage-by-stage advancement of the latch and corresponding increases in locked compressive preload.

In preferred embodiments, the cantilever includes a piezoelectric material such as PZT and the preload member includes a magnetostrictive material such as Terfenol-D. In certain preferred embodiments, the cantilever has a phi-spiral geometry configured to provide a cascade of resonant modes across a broader frequency range. The phi-spiral geometry is a preferred resonant-broadening embodiment and is not required in every embodiment of the invention.

In certain embodiments, the harvester employs both piezoelectric and magnetostrictive transduction mechanisms. In such embodiments, the combined transduction pathway can increase conversion effectiveness relative to either mechanism alone. Dual-transduction operation is a preferred efficiency-enhancing embodiment and does not define the broadest invention.

In representative embodiments, progressively increasing preload states produce stage-linked increases in open-circuit voltage, 3-dB bandwidth, mechanical Q-factor, and power density. Representative embodiments are further supported by random-vibration electrical testing, latch finite-element analysis, vibration cycling, and thermal cycling.

In certain optional embodiments, selected design relationships, performance relationships, or operating relationships may be verified using a formal proof system or other design-validation workflow. Such formal-verification embodiments may support optional claim families or continuation practice while remaining subordinate to the core passive staged-preload harvester architecture.

### BRIEF DESCRIPTION OF THE DRAWINGS

FIG. 1 is a perspective view of an overall MEMS harvester architecture including a piezoelectric cantilever, opposed magnetostrictive preload members, and a passive latch assembly. FIG. 1 illustrates the general spatial relationship among the cantilever, the preload structure, the latch structure, and representative package-level components of the harvester.

FIG. 2 is a top plan view of a preferred cantilever and preload-frame geometry, including a preferred phi-spiral cantilever embodiment. FIG. 2 further illustrates a representative balanced arrangement of opposed preload members relative to the cantilever and shows how the preferred cantilever geometry may be configured for broader-band response.

FIG. 3 is an enlarged view of a passive latch mechanism in a baseline state. FIG. 3 illustrates representative latch components including a pawl, a cam, and associated engagement features prior to advancement into a higher preload state.

FIG. 4 is a multi-panel sequence view illustrating latch advancement and corresponding preload-state progression. FIG. 4 shows representative stage-by-stage movement of the latch and corresponding changes in locked preload state as vibration amplitude increases.

FIG. 5 is a cross-sectional view of a cantilever and transducer stack. FIG. 5 illustrates representative layer ordering, including structural, piezoelectric, electrode, and preload-related features, and further shows a representative compressive load path acting on the cantilever.

FIG. 6 is a process-flow view illustrating representative fabrication stages for the harvester. FIG. 6 shows an example sequence including structural patterning, magnetostrictive-material formation, piezoelectric-material formation, electrode formation, release, and protective layer formation.

FIG. 7 is a threshold-to-preload mapping diagram showing relationships among vibration thresholds, latch advancement, and locked preload states. FIG. 7 further illustrates representative stage logic by which increasing vibration amplitude corresponds to increasing latch displacement and increasing compressive preload.

FIG. 8 is a system-level diagram showing output conditioning and integration of the harvester with downstream circuitry. FIG. 8 illustrates representative coupling of the harvester to rectification, storage, regulation, sensing, and communication components.

FIG. 9 is a performance-comparison figure showing representative output and bandwidth improvements across preload states. FIG. 9 may include comparative plots or other visualizations of voltage, bandwidth, Q-factor, power density, or related performance metrics for unloaded and preloaded operating states.

FIG. 10 is a reliability figure showing representative vibration-cycling and thermal-cycling results. FIG. 10 illustrates example durability, latch-retention, and performance-stability behavior under extended cycling and environmental stress conditions.

FIG. 11 is a deployment figure illustrating representative downstream use embodiments. FIG. 11 shows example implementations in self-powered sensing, telemetry, biomedical, industrial, infrastructure, or other vibration-powered applications.

### DETAILED DESCRIPTION OF THE INVENTION

Reference will now be made in detail to representative embodiments of the invention, examples of which are illustrated in the accompanying drawings. Wherever possible, like reference numerals are used to refer to like or corresponding parts throughout the drawings. The embodiments described herein are illustrative and are provided to enable those of ordinary skill in the art to make and use the invention. Unless expressly stated otherwise, features described in connection with one embodiment may be used in other embodiments, and no described feature, sequence, dimension, material, parameter, orientation, or performance value should be understood as required in all embodiments. Directional or relational terms, if used, are used for convenience of description and do not require a particular absolute orientation or arrangement unless expressly recited. Various modifications may be made without departing from the spirit and scope of the invention as defined by the claims.

No feature, characteristic, step, numerical value, theory, analytical framework, validation workflow, or other descriptive detail disclosed in connection with any illustrated or described embodiment should be understood as limiting any claim unless expressly recited in that claim. Subject matter described as preferred, optional, representative, exemplary, theory-linked, formally verified, or associated with a particular implementation is provided to illustrate the invention and to support particular embodiments, but does not define all embodiments of the invention. The claims, and not isolated descriptive examples, define the scope of the claimed invention.

The invention is a passive, vibration-driven, discrete preload-state architecture for a MEMS vibration energy harvester. More particularly, the invention provides a harvester in which a piezoelectric cantilever is mechanically coupled to at least one magnetostrictive preload member, and a passive latch advances and locks the preload member into discrete preload states in response to vibration amplitude. Through this arrangement, the harvester adaptively changes compressive preload applied to the cantilever without standby electrical power, thereby improving harvesting behavior across changing vibration conditions. This staged passive preload-state architecture is the core invention. In preferred embodiments, the harvester may further include balanced opposed preload members, a pawl-and-cam latch, a phi-spiral cantilever geometry, dual piezoelectric and magnetostrictive transduction pathways, formal verification workflows, or theory-linked analyses, but those features are not required in every embodiment unless expressly stated.

In broad form, the invention includes a piezoelectric cantilever, at least one magnetostrictive preload member mechanically coupled to apply compressive preload to the cantilever, and a passive latch configured to lock the preload member in two or more discrete preload states. In preferred embodiments, the passive latch is driven by the vibration being harvested and is self-locking such that, after advancement to a selected preload state, the latch maintains that state until a deliberate reset is applied. In preferred embodiments, the preload states correspond to increasing vibration-amplitude thresholds and progressively increasing compressive preload imposed on the cantilever.

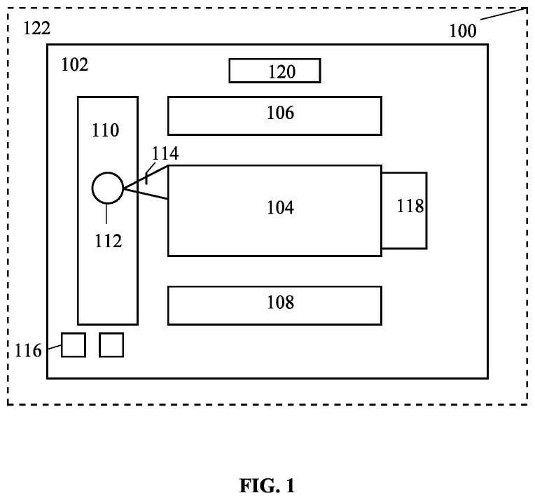

With reference first to FIG. 1, a representative harvester device 100 includes a substrate or frame 102 supporting a piezoelectric cantilever 104, a first magnetostrictive preload member 106, a second magnetostrictive preload member 108, and a latch assembly 110. In the illustrated preferred embodiment, the preload members 106, 108 are arranged on opposite sides of the cantilever 104 so as to provide a balanced compressive loading path. The latch assembly 110 includes a passive advancement mechanism configured to selectively change the effective mechanical condition of one or both preload members 106, 108, thereby changing the compressive preload applied to the cantilever 104.

The device 100 is configured to receive ambient vibration as an input. In use, vibration amplitude and frequency content cause mechanical excitation of the harvester structure. When the vibration amplitude exceeds one or more threshold levels, the latch assembly 110 advances and locks into a corresponding preload state. The resulting locked state changes the compressive preload imposed on the cantilever 104, which in turn changes the electrical-generation behavior of the harvester. The principal outputs of the device are electrical voltage, current, and power derived from vibration-induced strain in the cantilever 104 and, in preferred dual-transduction embodiments, from magnetically coupled transduction effects associated with the preload structure.

The operation of the device may include receipt of ambient vibration, mechanical response of the latch assembly 110 to vibration amplitude, advancement of the latch into a selected state when a threshold condition is reached, locking of the preload member or preload members in the selected state, imposition of corresponding compressive preload on the cantilever 104, and conversion of vibration-induced strain into electrical output. This staged passive operation distinguishes the present invention from fixed-preload and electrically biased tuning arrangements.

In the illustrated embodiment, the latch assembly 110 may include an inertial cam 112 and a pawl 114. The inertial cam 112 is configured to respond to vibration-driven motion, and the pawl 114 is configured to engage one or more latch features so as to hold a selected preload state after advancement. Electrical output may be routed through one or more output pad regions 116. In some embodiments, a proof mass 118 may be coupled to the vibrating structure to tailor response characteristics, and in some embodiments a magnetic bias structure 120 and package boundary 122 may be provided depending on packaging, tuning, or deployment requirements.

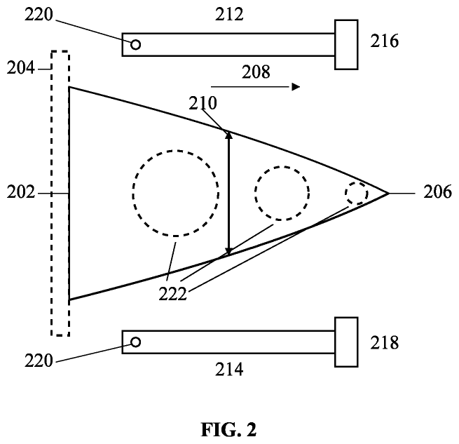

With reference to FIG. 2, the cantilever 104 may be formed as a structural beam carrying a piezoelectric transducer region. In a preferred embodiment, the cantilever body 202 extends from an anchor 204 toward a tip region 206 and is mechanically associated with the preload members 212, 214 through corresponding anchor regions 216, 218 and one or more latch-coupling interfaces 220. In certain preferred embodiments, the cantilever has a phi-spiral geometry in which local width 210 varies along an arc-length direction 208 according to the relation:

w(s)=w0/phi\hat{ }(s/L)

where w(s) is local width as a function of arc length s, w0 is a reference width, phi is the golden ratio, and L is a reference length scale. In such preferred embodiments, the geometry can provide a cascade of resonant modes represented generally by resonance markers 222. Although a phi-spiral cantilever is preferred, other cantilever geometries may be used while retaining the passive staged-preload architecture.

The cantilever 104 serves as the principal piezoelectric transduction structure. In operation, ambient vibration induces bending and strain in the cantilever, and the compressive preload imposed by the preload members alters the cantilever operating condition. In representative embodiments, increasing preload increases open-circuit voltage, broadens the 3-dB bandwidth, increases mechanical Q-factor, and increases power density relative to an unloaded condition, as described further below. The cantilever may include one or more piezoelectric layers, electrode structures, and structural support layers arranged to generate electrical output under vibration-induced strain.

With continued reference to FIGS. 1 and 2, at least one magnetostrictive preload member is mechanically coupled to the cantilever so as to impose compressive preload on the cantilever and thereby change the cantilever operating condition. In the illustrated preferred embodiment, the first preload member 106 and the second preload member 108 are arranged on opposite sides of the cantilever 104 to provide a balanced preload path. In another embodiment, a single preload member may be used. In other embodiments, more than two preload members or alternative balanced or asymmetric arrangements may be used, provided that the preload structure remains mechanically coupled to the cantilever and cooperates with the passive latch to establish discrete preload states.

In preferred embodiments, the preload members 106, 108 comprise magnetostrictive beam structures, and in a particularly preferred embodiment the preload members comprise Terfenol-D micro-beams. The preload members are configured such that vibration-associated magnetic or magnetoelastic response produces mechanical action contributing to compressive loading of the cantilever 104. In the preferred dual-member arrangement, the preload members 106, 108 are positioned and anchored so that the loading applied to the cantilever is substantially balanced across the cantilever structure. Balanced loading can improve cantilever stability, reduce undesirable off-axis loading effects, and improve repeatability of staged preload behavior. However, the invention is not limited to a particular beam count or symmetry so long as the disclosed passive staged-preload function is maintained.

In the preferred embodiment, the preload members are mechanically linked to the latch assembly 110 such that advancement of the latch changes the effective mechanical condition of the preload members. More particularly, each advancement of the latch may shorten an effective length, alter a retained displacement, or otherwise change the load-transmission state of the preload members so that a corresponding compressive preload is applied and then locked onto the cantilever 104. In this manner, the preload members and latch assembly cooperate to produce a set of discrete, mechanically retained preload states rather than a continuously adjusted or actively powered bias condition.

In a preferred modeling relation for the magnetostrictive preload structure, axial stress generated by a preload member may be expressed as:

sigma_m=Y_m×lambda_eff

where sigma_m is axial stress, Y_m is the Young's modulus of the magnetostrictive material, and lambda_eff is an effective magnetostrictive strain associated with the locked operating state. In one representative preferred embodiment, Y_m is about 50 GPa for Terfenol-D and lambda_eff is about 148×10\hat{ }−6 in a highest disclosed preload state, corresponding to an axial stress of about 7.4 MPa. These values are representative of one working embodiment and are provided to illustrate a useful operating regime rather than to limit the invention to a particular material constant or stage value.

In a preferred implementation, a magnetic bias structure establishes a bias field through the magnetostrictive preload member, and vibration-induced strain or motion modulates the magnetoelastic state of the preload member. The latch-linked preload link changes an effective retained displacement or effective beam length of the preload member, so that engagement of each latch state mechanically transfers a corresponding compressive load through the frame into the piezoelectric cantilever. Once the pawl engages a locking position, the retained displacement and associated compressive load are held by mechanical interference rather than by continuous electrical drive.

The compressive preload imposed by the preload member or preload members is transferred to the cantilever 104 through the mechanical coupling path established by the harvester frame and latch-linked preload structure. As preload increases across successive locked states, the cantilever experiences corresponding changes in strain state and electromechanical response. In preferred embodiments, this staged preload action improves coupling behavior and contributes to increases in voltage output, effective bandwidth, and power density. The preload members therefore do more than merely bias the structure; they cooperate with the latch to define selectable operating states of the harvester.

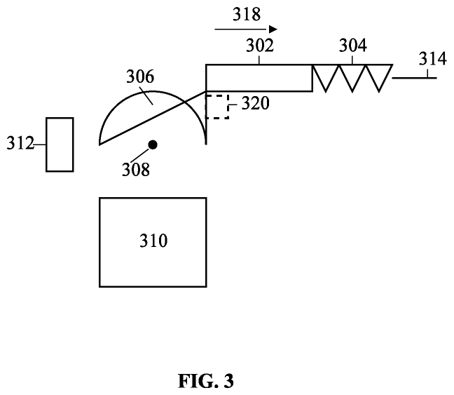

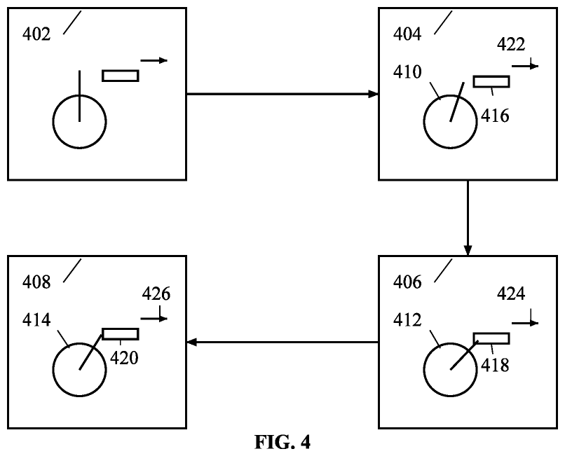

With reference now to FIGS. 3 and 4, the latch assembly 110 is the central passive state-selection mechanism of the harvester. The latch assembly advances and locks discrete preload states in response to vibration amplitude and holds those states without standby electrical power. In broad form, the latch assembly may be any passive mechanically responsive locking structure capable of advancing into two or more discrete preload states under vibration-driven excitation and retaining a selected state after advancement. In the illustrated preferred embodiment, however, the latch assembly 110 comprises a silicon pawl-and-cam mechanism including a pawl 302, a pawl tooth set 304, a cam 306, a cam pivot 308, an inertial cam mass 310, a latch stop 312, and a preload link 314.

In operation, the inertial cam mass 310 responds to vibration of the device. When vibration amplitude exceeds a threshold associated with a next preload state, the cam 306 rotates about the cam pivot 308 and causes the pawl 302 to advance relative to the tooth set 304 in an advancement direction 318. This advancement changes the state of the preload link 314 and causes the preload member or preload members to assume a new mechanically retained condition corresponding to a higher compressive preload on the cantilever 104. Once the pawl 302 engages the next locking position, the selected preload state is held mechanically and without electrical holding power. The latch is therefore passive, vibration-driven, and self-locking.

In a preferred embodiment, the latch is configured as a monotonic multi-stage structure progressing from a baseline state to a plurality of successively higher preload states. With particular reference to FIG. 4, a baseline state 402 may correspond to an unloaded or minimally preloaded condition. A first locked state 404 corresponds to a first threshold crossing and a first discrete increase in preload. A second locked state 406 corresponds to a second threshold crossing and a further discrete increase in preload. A third locked state 408 corresponds to a third threshold crossing and a still higher preload condition. Although three discrete locked states are preferred and are specifically disclosed, the latch may be configured to provide two or more discrete preload states.

In one representative preferred embodiment, the latch advances in approximately 3 micrometer increments. In a corresponding preferred three-stage implementation, a first threshold indicator 410 is associated with a first threshold vibration level of about 50 mg and a first pawl advance 422 into a first locked preload state. A second threshold indicator 412 is associated with a second threshold vibration level of about 120 mg and a second pawl advance 424 into a second locked preload state. A third threshold indicator 414 is associated with a third threshold vibration level of about 250 mg and a third pawl advance 426 into a third locked preload state. Representative corresponding cam angles may include a first cam angle 416 of about 12 degrees, a second cam angle 418 of about 24 degrees, and a third cam angle 420 of about 36 degrees. These values are preferred values from one working embodiment and are not required in every embodiment.

In a representative preferred stress ladder, the first locked state corresponds to a compressive preload of about 2.5 MPa, the second locked state corresponds to a compressive preload of about 5.0 MPa, and the third locked state corresponds to a compressive preload of about 7.4 MPa. The latch therefore provides not merely positional indexing, but a mechanically retained operating-state ladder for the harvester. Increasing vibration amplitude causes threshold-responsive advancement into progressively higher preload states, and each locked state can be maintained without continuous electrical bias or control power.

The latch is also preferably resettable. In the preferred embodiment, reverse motion does not occur during ordinary harvesting operation and instead requires a deliberate reset action, represented generally by reset feature 320. This reset functionality may be implemented mechanically, manually, or by another deliberate state-clearing action depending on packaging and deployment needs. The important point is that the latch does not drift continuously under ordinary operation. Rather, it holds a selected preload state until intentionally reset, thereby preserving the advantages of passive state retention and zero standby power.

In one representative finite-element analysis of the preferred latch, engage time is about 22 microseconds and peak tooth shear stress is about 280 MPa, corresponding to approximately 30 percent of the yield stress of crystalline silicon. These values indicate that the preferred latch can be configured for rapid engagement and acceptable mechanical margin. Such values are representative of one analyzed embodiment and may vary depending on tooth geometry, material selection, dimensions, and targeted threshold settings.

The latch assembly 110 may be understood as defining a passive mechanical state machine for the harvester. The inputs to that state machine are vibration amplitude and associated inertial response. The state-transition logic is threshold responsive. The output of the state machine is a selected discrete preload condition applied to the cantilever. This threshold-driven, mechanically retained preload-state architecture differs from fixed-preload arrangements and electrically powered tuning systems.

In preferred embodiments, the harvester employs both piezoelectric and magnetostrictive transduction mechanisms. The piezoelectric cantilever 104 converts vibration-induced strain into electrical charge, while the magnetostrictive preload structure can contribute an additional transduction pathway associated with magnetoelastic response of the preload members. Dual-transduction operation is a preferred efficiency-enhancing embodiment and does not define every embodiment of the invention.

The piezoelectric transduction pathway may be understood as arising from stress and strain within the cantilever 104 and associated piezoelectric material layers. As the cantilever vibrates, strain in the piezoelectric region produces an electrical potential that may be collected through one or more conductive routing paths and output pad regions. The magnetostrictive pathway may be understood as arising from vibration-coupled magnetoelastic behavior of the preload members, which in preferred embodiments can contribute to overall energy-conversion behavior. The two pathways may operate together in the same device and, in preferred embodiments, provide improved overall performance relative to either mechanism operating alone.

In a preferred relation for combined operation, overall conversion efficiency may be expressed as:

eta_combined=1−(1-eta_piezo)×(1-eta_magneto)

where eta_combined is a combined efficiency term, eta_piezo is piezoelectric conversion efficiency, and eta_magneto is magnetostrictive conversion efficiency. In preferred embodiments, the combined efficiency exceeds the individual efficiency of either conversion mechanism acting alone. This relationship is useful for describing a preferred mode of operation, but it is not required for every embodiment of the invention.

The open-circuit voltage produced by the cantilever may, in one representative linear approximation, be expressed as:

V_oc=(d31×sigma_m×L)/t_p

where V_oc is open-circuit voltage, d31 is a piezoelectric coefficient, sigma_m is preload-related stress, L is an effective cantilever length, and t_p is piezoelectric thickness. In one representative preferred embodiment, d31 is about −274 pC/N for PZT-5H, L is about 2.34 mm, t_p is about 0.6 micrometers, and a highest disclosed preload state corresponds to sigma_m of about 7.4 MPa, yielding an open-circuit voltage of about 7.9 V. These values are illustrative of one preferred implementation and are not intended to limit the invention to a particular coefficient, dimension, or output level.

In preferred staged embodiments, intermediate preload states may exhibit behavior that deviates from a strictly linear extrapolation from the highest preload state. For example, nonlinear improvements in magnetoelastic coupling may occur as compressive preload increases and improves domain alignment in the magnetostrictive material. Accordingly, measured or simulated voltage increases across preload stages may reflect both increasing locked preload and corresponding nonlinear coupling improvements. This staged behavior further supports the use of discrete preload states as operating-state controls for the harvester.

With further reference to FIG. 2, the cantilever may in preferred embodiments be configured with a broadband resonance-shaping geometry. In one particularly preferred embodiment, the cantilever has a phi-spiral profile in which local width varies according to:

w(s)=w0/phi\hat{ }(s/L)

where w(s) is local width along arc length s, w0 is a reference width, phi is the golden ratio, and L is a reference length parameter. This preferred geometry may provide a resonant cascade in which modal frequencies follow the relation:

f_n=f0×phi\hat{ }n

where f_n is the frequency of a selected mode and f0 is a base modal frequency. In such embodiments, the cantilever can capture energy across a broader vibration band than a simple fixed-width cantilever. The phi-spiral geometry is therefore a preferred resonant-broadening embodiment that can work synergistically with the staged preload architecture. However, the phi-spiral embodiment is not required in all embodiments, and other cantilever geometries may be used so long as the passive staged-preload architecture is maintained.

The combination of the broadband resonance-shaping geometry and the passive multi-stage preload architecture can be particularly advantageous. The preferred geometry broadens the frequency range over which useful cantilever response occurs, while the discrete preload-state architecture adaptively changes the cantilever operating condition as vibration amplitude changes. Together, these effects can improve practical energy harvesting in broadband and variable-amplitude environments. The phi-spiral embodiment is a preferred enhancement and is not required in all embodiments.

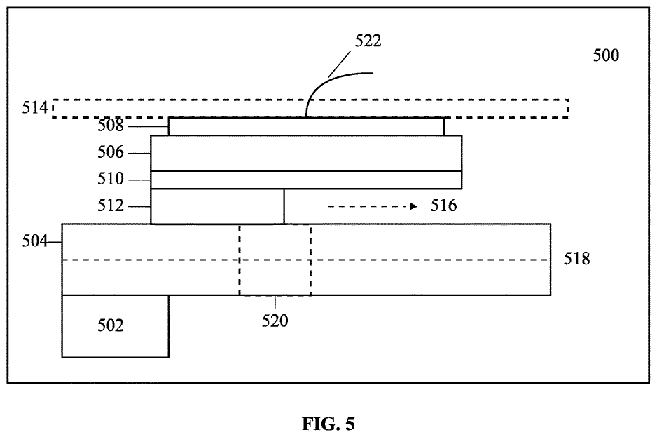

With reference now to FIG. 5, a representative cross-sectional transducer stack 500 is shown. In the illustrated embodiment, the stack 500 includes a substrate 502, a structural layer 504, a piezoelectric layer 506, a top electrode 508, and a lower electrode region 510. A magnetostrictive member 512 is mechanically associated with the cantilever structure so as to contribute to compressive preload, and a protective cap 514 may be provided over selected regions. A compressive load path 516 is transferred through the structure to affect the cantilever operating condition. A neutral axis 518, strain region 520, and output routing path 522 may also be defined within the illustrated stack. FIG. 5 therefore illustrates representative layer ordering and load transfer within a preferred cantilever and transducer arrangement.

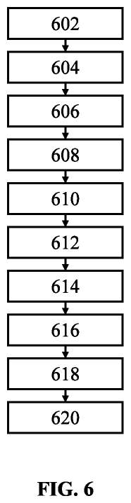

With reference now to FIG. 6, representative fabrication embodiments of the harvester will be described. In a preferred implementation, the device is fabricated using an SOI-based MEMS process flow that forms the cantilever, latch features, preload structures, and associated electrical layers in a compact integrated structure. The disclosed fabrication sequence provides one concrete make-and-use route for the invention.

In one representative embodiment, fabrication begins with an SOI starting wafer 602. Structural features of the harvester, including the cantilever, inertial cam features, and pawl teeth, may be patterned in a device layer using deep reactive ion etching to form DRIE-patterned features 604. In a preferred embodiment, the device layer is approximately 10 micrometers thick, although other structural thicknesses may be used depending on the desired mechanical response, fabrication process, and packaging constraints.

After structural patterning, a magnetostrictive material layer 606 may be formed. In a preferred embodiment, the magnetostrictive material comprises Terfenol-D deposited to a thickness of about 6 micrometers. Following deposition, the magnetostrictive region 608 may be field-annealed. In a representative preferred embodiment, field annealing is performed at about 400 degrees Celsius in a magnetic fixture providing a field of about 2 tesla so as to establish a desired easy axis in the magnetostrictive material. Other magnetostrictive formation and conditioning processes may be used, provided that the resulting structure remains compatible with the disclosed passive staged-preload architecture.

A piezoelectric layer 610 may then be formed on the cantilever structure. In a preferred embodiment, the piezoelectric layer comprises PZT-5H deposited by sol-gel processing using approximately five spin-and-bake cycles to yield a thickness of about 0.6 micrometers. The piezoelectric region 612 may then be poled, for example at about 150 V per micrometer, to establish piezoelectric response suitable for energy harvesting. Although these values are representative of a preferred embodiment, other piezoelectric materials, deposition approaches, and thicknesses may be used in embodiments preserving the disclosed passive staged-preload structure.

After piezoelectric formation, one or more conductive layers may be patterned to form electrode structures 614. In a preferred embodiment, a top electrode comprises about 200 nm of platinum, although other conductive materials and thicknesses may be employed. The device may then be released, for example to form a released device 616 by XeF2 processing or another release process appropriate for the selected MEMS structure. A protective cap 618 may then be formed over selected regions. In one representative embodiment, the protective cap comprises about 200 nm of ALD AlN. The completed structure is represented generally as final fabricated device 620. Representative fabrication tolerances may also be defined for one working embodiment. For example, a Terfenol-D beam width tolerance may be on the order of 110 nm at one standard deviation, and a latch tooth pitch tolerance may be on the order of 40 nm at one standard deviation. These values are illustrative of one fabricated embodiment and help demonstrate manufacturability, but they are not intended to require any specific tolerance window in all embodiments.

The disclosed fabrication sequence is intended to provide a concrete enabling route for making the preferred harvester structure. Alternative process sequences, alternative deposition techniques, alternative cap materials, and alternative device-layer thicknesses may be employed in other embodiments, provided that the resulting device still includes the disclosed passive, vibration-driven, discrete preload-state architecture involving a piezoelectric cantilever, at least one magnetostrictive preload member, and a passive latch that advances and locks preload states in response to vibration amplitude.

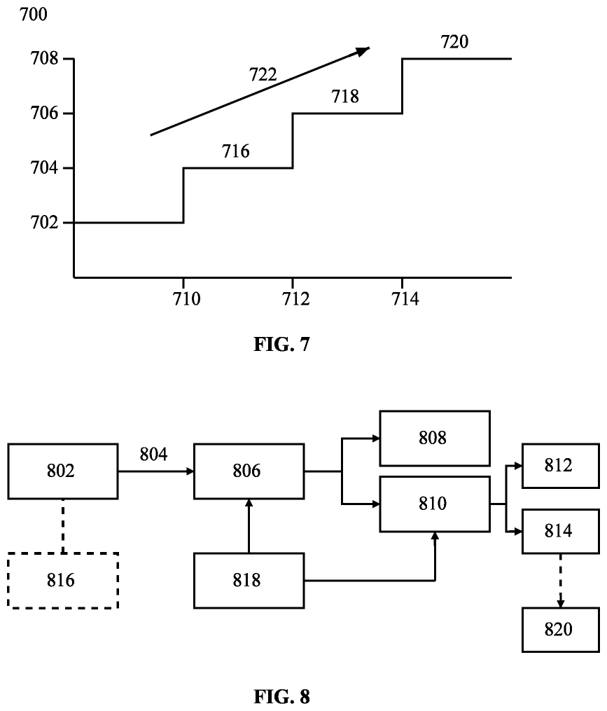

With reference now to FIG. 7, a representative threshold-to-preload mapping 700 is shown. In the illustrated embodiment, the mapping 700 includes a baseline region 702, a first threshold region 704, a second threshold region 706, and a third threshold region 708 corresponding to progressively increasing vibration-amplitude conditions. The mapping 700 further correlates these threshold regions with a first displacement 710, a second displacement 712, and a third displacement 714 of the latch structure or associated preload-link structure, and with a first locked stress 716, a second locked stress 718, and a third locked stress 720 imposed on the cantilever. A state-transition arrow 722 may be used to indicate progression from lower to higher locked preload states as vibration amplitude increases.

In a representative preferred embodiment, the baseline region 702 corresponds to an unloaded or minimally preloaded condition. The first threshold region 704 corresponds to advancement into a first locked preload state, the second threshold region 706 corresponds to advancement into a second locked preload state, and the third threshold region 708 corresponds to advancement into a third locked preload state. The associated displacements 710, 712, and 714 and locked stresses 716, 718, and 720 may increase in stepwise fashion so that increasing vibration amplitude produces a corresponding increase in retained compressive preload on the cantilever. FIG. 7 therefore provides a diagrammatic representation of the threshold-responsive state logic of the harvester and the correlation between vibration level, latch advancement, and locked preload condition.

In operation, the harvester receives ambient vibration as a mechanical input and converts at least a portion of that vibration into electrical output through a staged passive preload process. The operating method may include receipt of vibration by the cantilever and associated preload structure, mechanical response of the passive latch to vibration amplitude, advancement of the latch when a threshold condition is reached, locking of a corresponding preload state, imposition of the associated compressive preload on the cantilever, and generation of electrical output from the preloaded cantilever structure. This operating sequence may occur without standby electrical power for preload adjustment or preload retention.

In a representative method of operation, ambient vibration provides both the excitation to be harvested and the mechanical stimulus for state selection. When the device is exposed to vibration below a first threshold, the harvester may remain in a baseline or lower-preload state. When vibration amplitude exceeds a first threshold, the latch advances to a first locked preload state. When vibration amplitude exceeds a second threshold, the latch advances to a second locked preload state. When vibration amplitude exceeds a third threshold, the latch advances to a third locked preload state. In preferred embodiments, the stage progression is monotonic during ordinary harvesting operation, and reverse progression does not occur absent a deliberate reset.

The method inputs may include vibration amplitude, vibration frequency content, environmental operating conditions, and device-specific mechanical parameters. The method outputs may include open-circuit voltage, load voltage, current, harvested power, stored energy, or operation of a downstream electrical load. The internal method stages may include threshold-responsive latch actuation, mechanical state retention, preload transfer to the cantilever, strain-based electrical generation, and optional conditioning or storage of the generated output.

In a preferred method embodiment corresponding to the disclosed three-stage implementation, a first threshold crossing corresponds to a first locked compressive preload of about 2.5 MPa, a second threshold crossing corresponds to a second locked compressive preload of about 5.0 MPa, and a third threshold crossing corresponds to a third locked compressive preload of about 7.4 MPa. These preferred stage values are representative of one disclosed implementation and may vary in other embodiments. More generally, the method encompasses locking two or more discrete preload states in response to corresponding vibration thresholds.

The latch-retention portion of the operating method is significant. After advancement to a selected preload state, the latch mechanically retains that state without electrical holding power. This enables the harvester to adapt its operating condition while preserving harvested energy for useful output rather than consuming that energy to maintain bias or preload. In preferred embodiments, a reset operation may be applied when desired to return the latch to a lower-preload or baseline state. The reset may be manual, mechanical, or otherwise intentionally invoked depending on device packaging and deployment context.

With reference to FIG. 8, the harvester may be coupled to output conditioning and system-level circuitry. In a representative embodiment, a harvester module 802 is coupled through output leads 804 to a rectifier 806, a storage capacitor or battery 808, and a regulator 810. In some embodiments, the regulated output may power a sensor payload 812, a radio transceiver 814, or another downstream load. In some embodiments, the harvester may be associated with a monitored asset 816, and in some embodiments an optional controller 818 or external host 820 may be provided for supervisory or system-level functions. These system-level elements provide useful support for integrated device embodiments.

The output conditioning path may include impedance matching, rectification, storage, voltage regulation, duty-cycled loading, and load management depending on the needs of a target application. In one representative demonstrated embodiment, the harvester is operated with a matched load of about 18 kOhms. However, particular load values, rectifier topologies, storage components, or regulator architectures are not required in every embodiment. The present disclosure encompasses the harvester device itself, a packaged harvester module, and an integrated harvester system coupled to conditioning electronics and optional downstream circuitry.

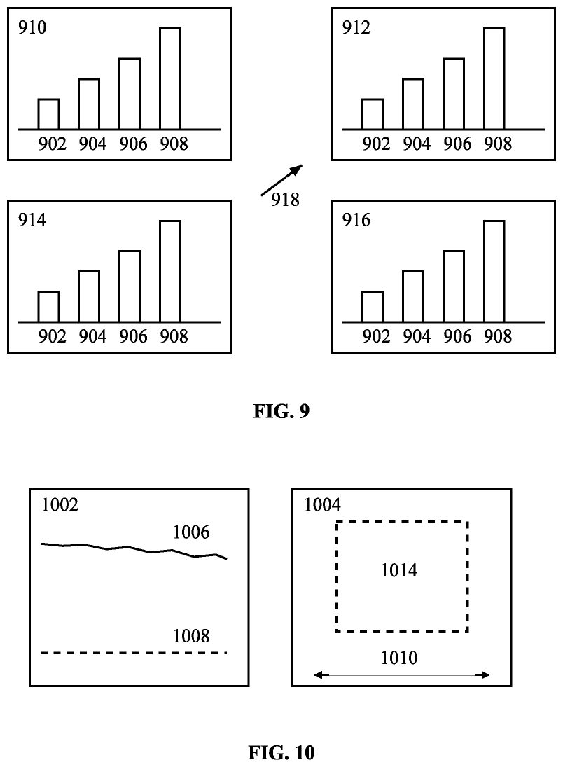

Representative demonstrated performance of the disclosed harvester will now be described with reference to FIG. 9. In one representative dataset, performance is compared among an unloaded cantilever condition 902, a first preload state 904, a second preload state 906, and a third preload state 908. Representative plotted or tabulated outputs may include a voltage plot 910, a bandwidth plot 912, a Q-factor plot 914, and a power-density plot 916. A trend indicator 918 may be used to illustrate the stage-linked increase in performance as preload state increases.

In one representative disclosed embodiment, the unloaded cantilever exhibits an open-circuit voltage of about 2.1 V, a 3-dB bandwidth of about 4 Hz, a Q-factor of about 25, and a power density of about 0.34 mW/cm\hat{ }3. A first preload state of about 2.5 MPa exhibits an open-circuit voltage of about 4.2 V, a 3-dB bandwidth of about 9 Hz, a Q-factor of about 42, and a power density of about 0.95 mW/cm\hat{ }3. A second preload state of about 5.0 MPa exhibits an open-circuit voltage of about 6.1 V, a 3-dB bandwidth of about 14 Hz, a Q-factor of about 55, and a power density of about 1.70 mW/cm\hat{ }3. A third preload state of about 7.4 MPa exhibits an open-circuit voltage of about 7.9 V, a 3-dB bandwidth of about 18 Hz, a Q-factor of about 68, and a power density of about 2.30 mW/cm\hat{ }3. These results illustrate that progressively increasing locked preload states can materially improve harvester output and bandwidth relative to an unloaded baseline.

In a representative random-vibration test, the harvester is exposed to vibration in a 40 Hz to 200 Hz band at about 80 mg RMS and operated into a load of about 18 kOhms. Under these representative conditions, the device exhibits about 3.6 V RMS, about 0.20 mA RMS, and about 0.72 mW total output power, corresponding to about 2.3 mW/cm\hat{ }3 normalized to a packaged volume that includes the die, proof mass, permanent-magnet bias, and MEMS package. These values provide concrete support for make-and-use disclosure and demonstrate the practical effectiveness of the staged passive preload architecture under broadband vibration conditions.

Representative performance characteristics may include one or more of the following: measurable stage-linked increase in voltage relative to an unloaded condition; measurable broadening of bandwidth relative to an unloaded condition; measurable increase in power density with increasing preload state; reliable latch advancement at intended threshold levels; and stable retention of selected preload states during sustained operation.

With reference to FIG. 10, representative reliability and robustness characteristics of the harvester will now be described. In one representative vibration-cycling result shown as vibration-cycling plot 1002, the device is subjected to about 10 million cycles at about 0.4 g and about 100 Hz. A corresponding power-fade trace 1006 indicates less than about 0.5 percent power fade, and a latch-slip trace 1008 indicates less than about 0.1 micrometers of latch slip. These results support the mechanical retention capability of the staged latch architecture and the stability of harvester performance under repeated excitation.

In a representative thermal-cycling result shown as thermal-cycling plot 1004, the device is cycled about 200 times across a temperature range indicated by temperature range indicator 1010, for example from about −40 degrees Celsius to about 125 degrees Celsius. In one representative embodiment, latch slip remains at or below about 0.3 micrometers, no PZT depolarization is observed, and Terfenol-D demagnetization remains below about 2 percent. These results support suitability of the preferred embodiment for environments involving temperature variation and extended operation. An acceptable-performance region 1014 may be used to indicate retention of useful device function within a selected reliability window.

The demonstrated performance and reliability data described above provide empirical support for the operability and robustness of the disclosed staged-preload architecture. These demonstrated results may be supplemented in other embodiments by alternative geometries, material systems, package configurations, or deployment conditions while preserving the core staged-preload mechanism of the invention.

In certain optional embodiments, one or more design relationships, operating relationships, or performance relationships associated with the harvester may be analyzed or verified using a formal proof system. Such formal verification may be used to confirm structural, modal, transduction-related, phase-related, or energy-related relationships associated with a selected harvester design. These formal-verification embodiments are optional and do not limit the passive, vibration-driven, discrete preload-state architecture described herein.

In representative optional embodiments, machine-verified or formally verified relationships may include a mode-ratio relationship associated with a preferred phi-spiral cantilever geometry, a combined-efficiency relationship for embodiments employing both piezoelectric and magnetostrictive transduction, a design-viability relationship for a selected harvester architecture, and one or more phase-related or extraction-related relationships associated with theory-linked operating frameworks. In such embodiments, formal verification may be used as a design-validation tool, a screening tool for candidate geometries or threshold settings, or a confirmation tool for selected analytical relationships used in connection with the harvester.

In certain optional theory-linked embodiments, extracted energy may be analyzed according to a framework in which a coherence quantum is defined as E_coh=phi\hat{ }-5 and in which selected extraction events may be represented as integer multiples of that quantity according to E_per_event=k×E_coh, where k is an integer. In certain optional embodiments, extraction timing or phase relationships may further be analyzed according to an eight-tick framework or other phase-window framework. These theory-linked embodiments may support selected analyses, embodiments, claim strategies, or continuation practice, but the core staged passive preload architecture disclosed herein is not limited to any particular theory-linked framework unless expressly recited.

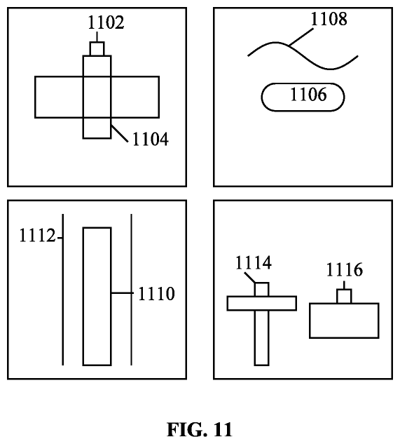

Representative downstream use embodiments of the disclosed harvester will now be described with reference to FIG. 11. These embodiments are provided to illustrate useful applications of the harvester and to support integrated system and deployment embodiments. These embodiments illustrate example applications of the disclosed harvester architecture.

In one representative embodiment, the harvester may be incorporated into a rotating-shaft monitor 1102 mounted on or near a bearing housing or shaft collar 1104. In such an implementation, vibration associated with shaft rotation, imbalance, bearing wear, or other machine conditions may serve as the energy source for the harvester. The generated electrical output may power one or more local sensing, logging, or wireless communication functions, thereby enabling self-powered condition monitoring of industrial motors, pumps, turbines, or related rotating equipment.

In another representative embodiment, the harvester may be incorporated into an implantable package 1106 associated with a physiological motion source 1108. In such an embodiment, body motion, tissue motion, pulse-driven motion, or other physiological vibration may act as the input excitation. The harvester may be configured to provide supplemental electrical energy for an implanted sensing, stimulation, monitoring, or fluid-delivery device. The specific package materials, encapsulation structures, and biomedical interfaces may vary depending on the target implantation context. These biomedical implementations are application embodiments and do not alter the disclosed staged-preload device architecture.

In a further representative embodiment, the harvester may be incorporated into a down-hole tool string 1110 or other telemetry assembly deployed in a drilling environment 1112. In such embodiments, vibration associated with drilling, production, fluid flow, or tool motion may supply the excitation used both to actuate staged preload selection and to generate electrical output. The resulting harvested power may be used for sensing, data logging, telemetry, or local electronics in high-vibration and elevated-temperature environments.

In other representative embodiments, the harvester may be deployed in a structural monitor 1114 for bridges, buildings, rails, pipelines, or other infrastructure, or in a vehicle-mounted sensor 1116 such as a tire-pressure, chassis, suspension, or road-condition sensor. Additional representative deployments include railway monitors, UAV and drone vibration scavengers, and other systems in which ambient vibration is present and local power availability is constrained. In each such case, the deployment context may change, but the harvester may retain the same passive, vibration-driven, discrete preload-state MEMS architecture.

In any of the foregoing downstream embodiments, the harvester may be used as a stand-alone energy source, as a supplemental energy source, or as part of a hybrid power architecture including a storage element, conditioning circuit, or other power-management structure. The generated output may be used continuously, intermittently, or in a duty-cycled manner depending on the needs of the downstream load. These use cases illustrate the versatility of the disclosed harvester and do not redefine the disclosed staged passive preload architecture.

1. A micro-electromechanical vibration energy harvester, comprising: a piezoelectric cantilever;
at least one magnetostrictive preload member mechanically coupled to the piezoelectric cantilever and configured to apply compressive preload to the piezoelectric cantilever; and a passive latch mechanically coupled to the at least one magnetostrictive preload member and configured to advance and lock the at least one magnetostrictive preload member into two or more discrete preload states in response to vibration amplitude, wherein the two or more discrete preload states correspond to respective discrete compressive preload conditions of the piezoelectric cantilever, and wherein the passive latch retains a selected one of the discrete preload states without standby electrical power for preload retention.

2. The energy harvester of claim 1, wherein the passive latch is configured to retain a selected preload state without electrical holding power until a deliberate reset is applied.

3. The energy harvester of claim 1, wherein the passive latch is driven by vibration of the energy harvester.

4. The energy harvester of claim 1, wherein the passive latch comprises a pawl-and-cam mechanism.

5. The energy harvester of claim 4, wherein the pawl-and-cam mechanism comprises an inertial cam configured to rotate in response to vibration and a pawl configured to engage a locking position corresponding to one of the discrete preload states.

6. The energy harvester of claim 1, wherein the passive latch is configured to lock the at least one magnetostrictive preload member into at least three discrete preload states.

7. The energy harvester of claim 6, wherein the at least three discrete preload states correspond to progressively increasing vibration-amplitude thresholds of about 50 mg, about 120 mg, and about 250 mg.

8. The energy harvester of claim 1, comprising first and second magnetostrictive preload members arranged on opposite sides of the piezoelectric cantilever to provide balanced compressive loading.

9. The energy harvester of claim 1, wherein the at least one magnetostrictive preload member comprises Terfenol-D.

10. The energy harvester of claim 6, wherein, at a highest one of the at least three discrete preload states, the energy harvester exhibits at least one performance characteristic selected from the group consisting of an open-circuit voltage of about 7.9 V, a 3-dB bandwidth of about 18 Hz, a mechanical Q-factor of about 68, and a power density of about 2.30 mW/cm\hat{ }3.

11. The energy harvester of claim 6, wherein the at least three discrete preload states correspond to locked compressive preload levels of about 2.5 MPa, about 5.0 MPa, and about 7.4 MPa.

12. The energy harvester of claim 1, wherein the piezoelectric cantilever has a phi-spiral geometry.

13. A method of harvesting energy from vibration, comprising: receiving ambient vibration at a micro-electromechanical harvester having a piezoelectric cantilever and at least one magnetostrictive preload member mechanically coupled to the piezoelectric cantilever; passively actuating a latch in response to vibration amplitude; advancing the latch when the vibration amplitude exceeds a threshold; locking the at least one magnetostrictive preload member into one of two or more discrete preload states with the latch; imposing a corresponding compressive preload on the piezoelectric cantilever; and generating electrical output from the piezoelectric cantilever while the corresponding compressive preload is mechanically retained without standby electrical power for preload retention.

14. The method of claim 13, further comprising selecting at least one of a latch threshold, a preload level, a cantilever geometry, and an extraction window based on a computed energy-per-event value represented as an integer multiple of a coherence quantum E_coh, where E_coh=phi\hat{ }-5.

15. The method of claim 13, wherein passively actuating the latch comprises inertially actuating a cam and advancing a pawl into a locking position.

16. The method of claim 13, further comprising resetting the latch to a lower preload state by a deliberate reset action.

17. A method of fabricating a micro-electromechanical vibration energy harvester, comprising:
forming a piezoelectric cantilever and passive latch features in a device layer of a substrate;
forming at least one magnetostrictive preload member mechanically coupled to apply compressive preload to the piezoelectric cantilever; forming a piezoelectric layer on the piezoelectric cantilever; forming one or more electrode structures electrically coupled to the piezoelectric layer; and releasing the harvester structure such that the passive latch is configured to advance and lock the at least one magnetostrictive preload member into two or more discrete preload states in response to vibration amplitude.

18. The method of claim 17, further comprising using a formal proof system to generate or verify at least one design parameter selected from the group consisting of a cantilever width profile, a resonant-mode ratio, a preload-stage threshold, and a latch advancement distance before forming the harvester structure.

19. The method of claim 17, wherein forming the at least one magnetostrictive preload member comprises depositing Terfenol-D and field-annealing the deposited Terfenol-D.

20. The energy harvester of claim 1, further comprising a downstream electrical subsystem coupled to the energy harvester and comprising at least one of a rectifier, a storage element, a regulator, a sensor, a radio transceiver, a telemetry circuit, or a monitoring circuit.
